(19) United States
(12) Patent Application Publication
(10) Pub. No.: US 2025/0359353 A1
(43) Pub. Date: Nov. 20, 2025

(54) N-TYPE SOLAR CELL AND SOLAR CELL ASSEMBLY COMPRISING THE SAME

(71) Applicant: SEG Solar Inc., Houston, TX (US)

(72) Inventors: Jian ZHOU, Nanjing (CN); Fachao HE, Nanjing (CN); Zuyi WEI, Nanjing (CN); Jun ZHUGE, Houston, TX (US)

(21) Appl. No.: 18/801,601

(22) Filed: Aug. 12, 2024

(30) Foreign Application Priority Data
May 16, 2024 (CN) 202410606526.8
May 16, 2024 (CN) 202421063495.8

(51) Int. Cl. H01L 31/05; H01L 31/0216

(52) U.S. Cl. CPC H10F 19/904; H10F 19/906; H10F 77/315

(57) ABSTRACT

An N-type solar cell including: an N-type silicon substrate, an emitter layer, a first tunneling layer, at least one first doped polysilicon layer, a passivation layer, a first anti-reflection coating, a second tunneling layer, at least one second doped polysilicon layer, and a second anti-reflection coating. The emitter layer is disposed on a front surface of the N-type silicon substrate. The first tunneling layer is disposed on the emitter layer. The at least one first doped polysilicon layer is disposed on the first tunneling layer. The passivation layer is disposed on the at least one first doped polysilicon layer. The first anti-reflection coating is disposed on the passivation layer. The second tunneling layer is disposed on a rear surface of the N-type silicon substrate. The at least one second doped polysilicon layer is disposed on the second tunneling layer.

### CROSS-REFERENCE TO RELATED APPLICATIONS

Pursuant to 35 U.S.C. § 119 and the Paris Convention Treaty, this application claims foreign priority to Chinese Patent Application No. 202410606526.8 filed May 16, 2024, and to Chinese Patent Application No. 202421063495.8 filed May 16, 2024. The contents of all of the aforementioned applications, including any intervening amendments thereto, are incorporated herein by reference. Inquiries from the public to applicants or assignees concerning this document or the related applications should be directed to: Matthias Scholl P.C., Attn.: Dr. Matthias Scholl Esq., 245 First Street, 18th Floor, Cambridge, MA 02142.

### BACKGROUND

The disclosure relates to an N-type solar cell and a solar cell assembly comprising the same.

Conventional solar panel production involves: connecting multiple solar cells with interconnect ribbons to form solar strings; and then integrating the solar strings with other components to form a final solar panel. However, the production process lowers the overall efficiency of the solar cells for two main reasons: the interconnect ribbons take up space on the surface of the solar cells, reducing the effective light-receiving area of each solar cell; and gaps between adjacent solar cells within the solar strings are areas where there are no photovoltaic materials present, further reducing the effective light-receiving area.

P-type monocrystalline PERC (passivated emitter rear contact) solar cells have a theoretical limit to their conversion efficiency, which is 24.5%. Current industrial production lines achieve around 23.3% efficiency, which is close to the theoretical limit, leaving little room for significant improvement. However, challenges remain, particularly with light-induced degradation caused by boron-oxygen pairs in P-type silicon. The degradation limits further efficiency increases. In contrast, N-type cells, where electrons are the minority carriers, do not face the same degradation issues as P-type cells, where holes are minority carriers. In silicon wafers, impurities capture electrons more readily than holes. As a result, under the same conditions of metal impurity contamination, N-type cells exhibit lower surface recombination velocity and have minority carrier lifetimes that are 1-2 orders of magnitude higher than those of P-type cells. The extended lifetime enhances the open-circuit voltage and overall conversion efficiency of the N-type cells. Additionally, N-type silicon wafers have more uniform resistivity, resulting in a higher proportion of high-efficiency cells. The uniform resistivity across the substrate increases the high-efficiency output from the solar cells and enhances flexibility, potentially allowing for production of thinner silicon wafers.

The N-type silicon wafers are doped with phosphorus and have low boron content in crystalline silicon. The low boron content leads to minimal light-induced degradation caused by boron-oxygen pairs, almost reaching zero. As a result, the N-type silicon wafers experience less than 1% degradation in the first year, compared to the initial 2% degradation observed in P-type products. The N-type cells typically run at an average temperature about 0.5° C. lower than the P-type cells. The N-type cells have a lower temperature coefficient of −0.26% to −0.3% per degree Celsius, compared to −0.35% per degree Celsius for the P-type cells. The temperature coefficient difference means that the power output of the N-type cells decreases less as temperature increases, resulting in better overall performance and higher energy yield over time. The N-type cells have a superior response to weak light conditions, generating electricity even when irradiance is below 400 W/m². The superior response is particularly beneficial during early morning, evening, or overcast weather when sunlight is less intense. The N-type cells typically have an 85% bifacial coefficient compared to 70% for P-type PERC cells, resulting in approximately 3% additional electricity gain for end-users under standard ground reflectivity conditions. N-type high-efficiency solar cell technology, characterized by high conversion efficiency, low temperature coefficient, and reduced degradation from PID (Potential Induced Degradation), LID (Light-Induced Degradation), and LeTID (Light and Elevated Temperature Induced Degradation), is gaining significant attention and recognition in the industry. As a result, there is a trend towards replacing the P-type cells with N-type solutions. However, challenges persist in the application and production of the N-type cells.
(1) To achieve the electrical performance necessary for industrial-scale production, current N-type TOPCon (Tunnel Oxide Passivated Contact) solar cells require the use of silver paste on both the front and rear sides to form the necessary electrical contacts. The use of silver paste results in a higher consumption rate of the silver paste compared to PERC cells. N-type TOPCon cells use an average of 13-15 mg of the silver paste per Watt-peak (Wp), whereas PERC cells use about 9-10 mg of the silver paste per Wp.
(2) The current industry trend is to adopt Multi-Busbar (MBB) designs to reduce cost and improve efficiency. The MBB designs increase the number of the busbars, typically ranging from 12 to 18. However, adding more busbars complicates screen printing processes. Initially, increasing the number of busbars boosts efficiency, but there are diminishing returns. Beyond a certain point, adding more busbars does not enhance efficiency but increases complexity and cost. A stringer machine, which solders the solar cells together with the busbars, must be highly precise to handle the increased number of busbars. Additionally, with more busbars, the connecting copper wires need to be finer, usually with diameters greater than 0.2 mm.
(3) The stringing process of solar cells presents the following technical challenges: soldering at approximately 22° C. is necessary to achieve Ohmic contact with the busbars. Current stringer machine faces difficulties in maintaining temperature stability during prolonged operation and ensuring a reliable electrical connection between finer and more numerous interconnect ribbons and cells. The issues lead to soldering defects, including misalignment, voids, and excess solder. The soldering defects pose significant reliability risks for the solar cells.
(4) Conventional infrared soldering, used during the thermal cycling process of the solar cells, causes the materials in the solar cells to expand when heated, leading to mechanical stresses. The mechanical stresses can cause hidden cracks to form in the materials of the solar cells.
(5) Conventional busbars typically have a width of around 50 micrometers, while the copper wire has a diameter of around 0.28 mm. Due to the size difference, a contact area between the conventional busbars and the copper wire is minimal. The current stringer machines lack sufficient positioning accuracy, causing shifts in the soldering position. The misalignment can cause the copper wire to block portions of the surface of the solar cells, thereby leading to additional optical losses.

The challenges describe above impact the efficiency of assembling the solar cells into module products. The potential for further cost reduction has reached its limit, creating obstacles for the application and development of the N-type high-efficiency solar cell technology.

### SUMMARY

To solve the aforesaid problems, the first objective of the disclosure is to provide an N-type solar cell and a solar cell assembly comprising the same.

The N-type solar cell comprises an N-type silicon substrate, an emitter layer, a first tunneling layer, at least one first doped polysilicon layer, a passivation layer, a first anti-reflection coating, a second tunneling layer, at least one second doped polysilicon layer, and a second anti-reflection coating. The emitter layer is disposed on a front surface of the N-type silicon substrate; the first tunneling layer is disposed on the emitter layer; the at least one first doped polysilicon layer is disposed on the first tunneling layer; the passivation layer is disposed on the at least one first doped polysilicon layer; the first anti-reflection coating is disposed on the passivation layer; the second tunneling layer is disposed on a rear surface of the N-type silicon substrate; the at least one second doped polysilicon layer is disposed on the second tunneling layer; and the second anti-reflection coating is disposed on the at least one second doped polysilicon layer.

In a class of this embodiment, the N-type solar cell further comprises a plurality of first fingers and a plurality of second fingers; the plurality of first fingers are disposed on an outer side of the first anti-reflection coating; and the plurality of second fingers are disposed on an outer side of the second anti-reflection coating.

In a class of this embodiment, the first tunneling layer and the second tunneling layer comprise silicon dioxide.

In a class of this embodiment, the passivation layer comprises aluminum oxide.

The second objective of the disclosure is to provide a solar cell assembly. The solar cell assembly comprises at least one solar array. The at least one solar array comprises a plurality of solar cell strings connected in series and/or in parallel. Each of the plurality of solar cell strings comprises a first carrier film, a second carrier film, a plurality of low-temperature interconnect ribbons, and a plurality of N-type solar cells. The plurality of N-type solar cells are disposed side by side. Every two adjacent N-type solar cells are interconnected using one of the plurality of low-temperature interconnect ribbons. Specifically, one end of one of the plurality of low-temperature interconnect ribbons is connected to the front surface of one of the plurality of N-type solar cells, and the other end of the low-temperature interconnect ribbon is connected to the rear surface of the adjacent N-type solar cell. The first carrier film is disposed on the front surface of each of the plurality of N-type solar cells. The second carrier film is disposed on the rear surface of each of the plurality of N-type solar cells. The plurality of low-temperature interconnect ribbons are adhered to the first carrier film and the second carrier film, thereby forming the plurality of solar cell strings. The solar cell assembly further comprises a plurality of ribbons. The plurality of ribbons are disposed between the plurality of solar cell strings to collect and conduct electricity. The arrangement forms the at least one solar array.

In a class of this embodiment, the solar cell assembly further comprises a first encapsulant film, a second encapsulant film, a first sheet, and a second sheet. The first encapsulant film is disposed on a front surface of the at least one solar array. The second encapsulant film is disposed on a rear surface of the at least one solar array. The first sheet is disposed on the first encapsulant film, and the second sheet is disposed on the second encapsulant film.

In a class of this embodiment, the solar cell assembly further comprises a split-type junction box disposed on the second sheet.

In a class of this embodiment, the solar cell assembly further comprises a first frame and a second frame. A short edge of the at least one solar array is encapsulated with the first frame, and a long edge of the at least one solar array is encapsulated with the second frame.

In a class of this embodiment, the plurality of low-temperature interconnect ribbons are a plurality of low-temperature alloy copper wires.

The following advantages are associated with the disclosure:
(1) The disclosed N-type solar cell is a TOPCon solar cell that combines zero busbar (0BB) technology and half-cell technology. The design reduces the amount of silver needed in metallization process. The disclosure also employs the low-temperature alloy copper wires to interconnect the N-type solar cells, avoiding high-temperature soldering and reducing thermal stress on the N-type solar cells. The N-type solar cell is pre-cut into half cells to minimize the electrical losses typically caused by laser cutting processes, leading to lower overall power losses. The 0BB technology eliminates the optical losses due to the misalignment of solder wires and busbars. With a higher density of the low-temperature alloy copper wires, a distance that charge carriers need to travel to reach a collection point is reduced. The shorter distance leads to lower electrical resistance and reduced electrical losses as the charge carriers move through the N-type solar cells. Consequently, these improvements collectively reduce electrical losses when the N-type solar cells are assembled into the solar cell assembly.
(2) The disclosure achieves over 100% Cell-to-Module (CTM) efficiency, including contributions from double-sided coated glass, half-cut cells, 0BB technology, and light conversion films.
(3) The disclosure utilizes a low-temperature method to interconnect the N-type solar cells, thereby reducing internal stress and improving the reliability and lifespan of the N-type solar cells. The disclosure also reduces the silver paste usage by 20% and incorporates thinner silicon wafers and encapsulation materials, lowering the production costs. The low-temperature method is carried out at approximately 150° C., resulting in decreased energy consumption and operational costs. Additionally, the use of lead-free packaging materials and the elimination of a flux process contribute to a more eco-friendly and sustainable production by reducing harmful substances.
(4) The disclosure eliminates PAD points and utilizes thinner low-temperature alloy copper wires that are evenly distributed across the N-type solar cells. The design enhances the appearance of the N-type solar cells and reduces reflectivity at solder strip locations.
(5) The disclosure reduces solar cell production costs by using less silver paste, thinner silicon wafers, and lighter encapsulant films. The changes lead to lower production costs and reduced carbon emissions compared to the conventional methods.

### BRIEF DESCRIPTION OF THE DRAWINGS

FIG. 1 is a schematic diagram of an N-type solar cell according to one example of the disclosure;

FIG. 2 is a graphical representation of an N-type solar cell according to one example of the disclosure;

FIG. 3 is a schematic diagram of a solar cell string according to one example of the disclosure;

FIG. 4 is a schematic diagram of a stacked structure of a solar cell assembly according to one example of the disclosure;

FIG. 5 is a schematic diagram of a laminated structure of a solar cell assembly according to one example of the disclosure;

FIG. 6 is a schematic diagram of a solar cell assembly according to one example of the disclosure; and

FIG. 7 is an enlarged view of part A in FIG. 6.

In the drawings, the following reference numbers are used: 1. N-type silicon substrate; 2. Emitter layer; 3. First tunneling layer; 4. First doped polysilicon layer; 5. Second tunneling layer; 6. Second doped polysilicon layer; 7. Passivation layer; 8. First anti-reflection coating; 9. Second anti-reflection coating; 10. First finger; 11. Second finger; 12.1. First carrier film; 12.2 Second carrier film; 13. Low-temperature interconnect ribbon; 14. N-type solar cell; 15.1. First encapsulant film; 15.2. Second encapsulant film; 16.1. First sheet; 16.2. Second sheet; 17. Solar cell string; 18. Split-type junction box; 19.1. First frame; 19.2. Second frame; and 20. Ribbon.

### DETAILED DESCRIPTION

### Example 1

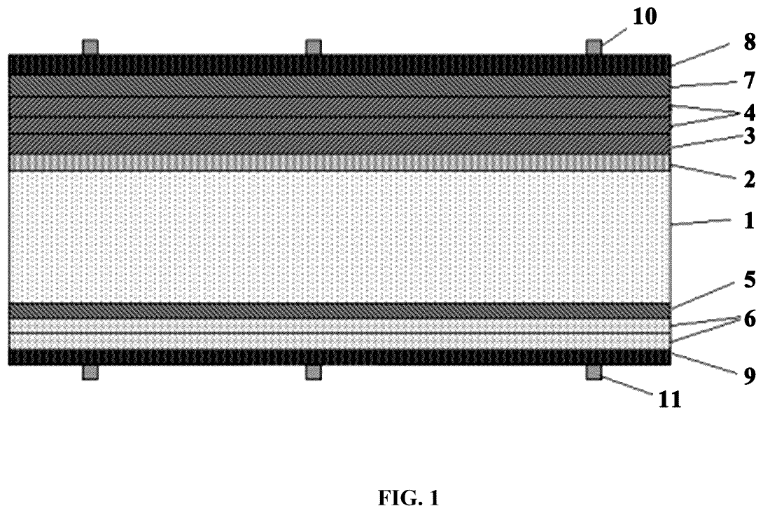

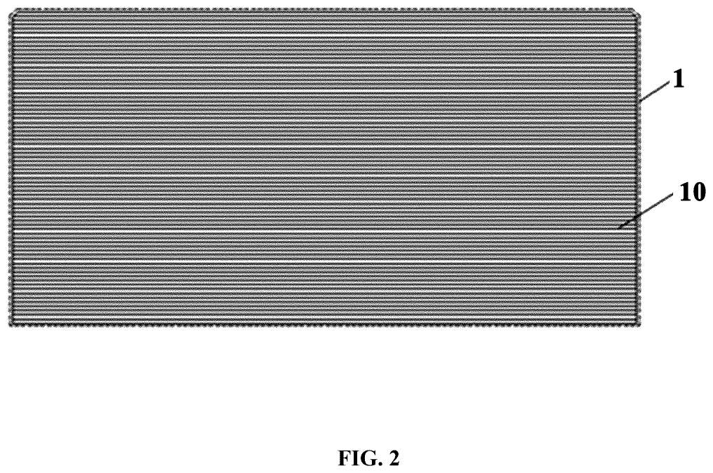

As shown in FIGS. 1-2, an N-type solar cell comprises an N-type silicon substrate 1, an emitter layer 2, a first tunneling layer 3, at least one first doped polysilicon layer 4, a passivation layer 7, a first anti-reflection coating 8, a second tunneling layer 5, at least one second doped polysilicon layer 6, and a second anti-reflection coating 9. The emitter layer is disposed on a front surface of the N-type silicon substrate; the first tunneling layer 3 is disposed on the emitter layer; the at least one first doped polysilicon layer 4 is disposed on the first tunneling layer 3; the passivation layer 7 is disposed on the at least one first doped polysilicon layer 4; the first anti-reflection coating 8 is disposed on the passivation layer 7; the second tunneling layer 5 is disposed on a rear surface of the N-type silicon substrate; the at least one second doped polysilicon layer 6 is disposed on the second tunneling layer 5; and the second anti-reflection coating 9 is disposed on the at least one second doped polysilicon layer 6.

The N-type solar cell further comprises a plurality of first fingers 10 and a plurality of second fingers 11. The plurality of first fingers 10 are disposed on an outer side of the first anti-reflection coating 8. The plurality of second fingers 11 are disposed on an outer side of the second anti-reflection coating 9. Specifically, the plurality of first fingers 10 are printed on the first anti-reflection coating 8, and the plurality of second fingers 11 are disposed on the second anti-reflection coating 9; subsequently, the plurality of first fingers 10 and the plurality of second fingers 11 are subjected to a sintering process; the sintering process causes the plurality of first fingers 10 and the plurality of second fingers 11 to penetrate the first anti-reflection passivation layer 8 and the anti-reflection passivation layer 9, respectively, thereby forming an ohmic contact with the at least one first doped polysilicon layer 4 and the at least one second doped polysilicon layer 6; following the sintering process, light injection is performed; and then a light-receiving surface of the N-type solar cell is sintered using a laser and a reverse voltage.

The first tunneling layer 3 and the second tunneling layer 5 comprise silicon dioxide. The passivation layer 7 comprises aluminum oxide. The at least one first doped polysilicon layer 4 comprises an n+ polysilicon film.

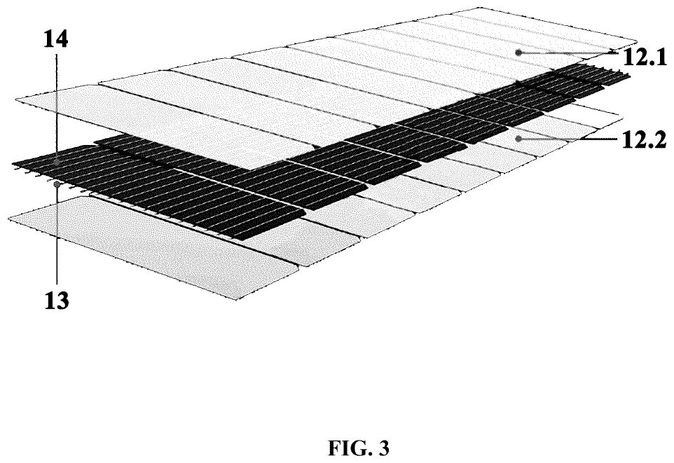

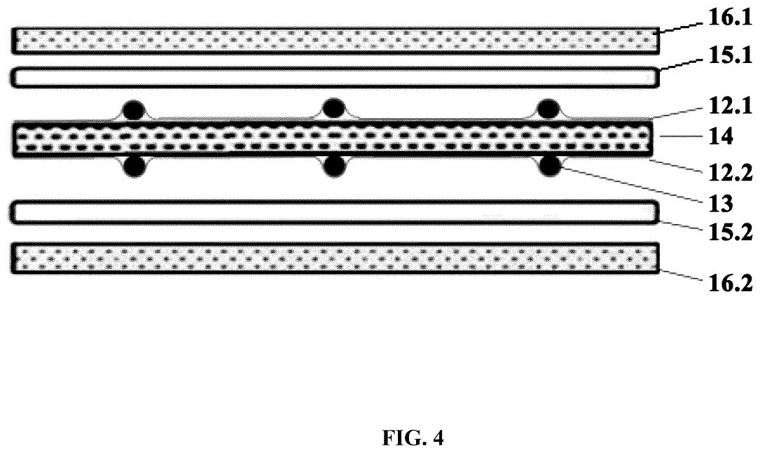

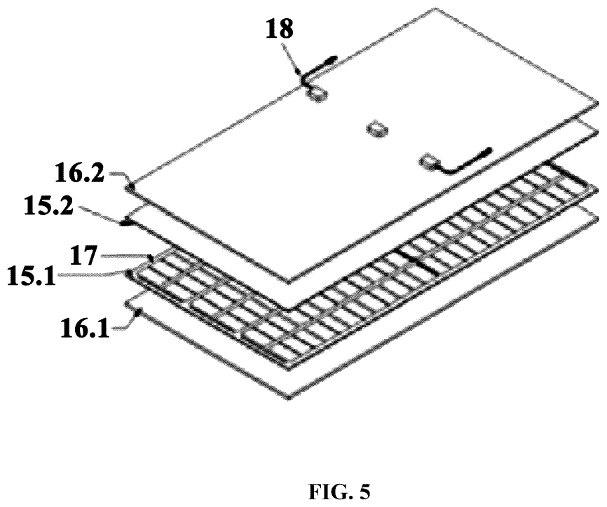

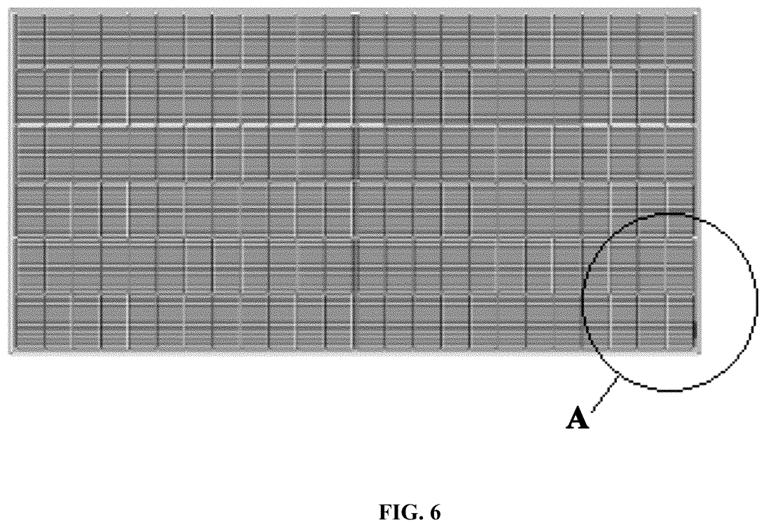

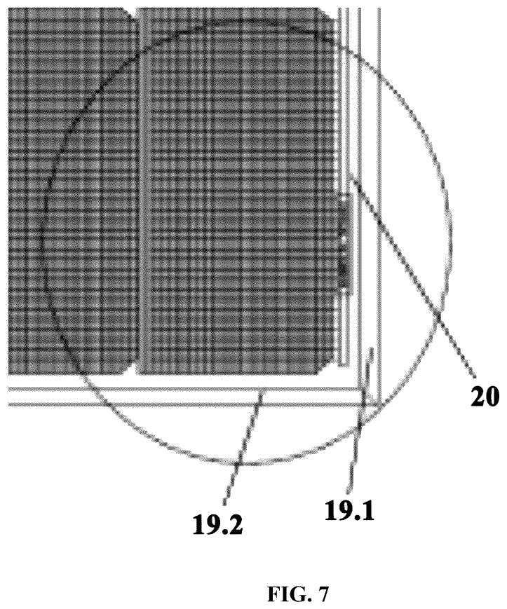

As shown in FIGS. 3-7, a solar cell assembly comprises a plurality of at least one solar array. The at least one solar array comprises a plurality of solar cell strings connected in series and/or in parallel. Each of the plurality of solar cell strings comprises a first carrier film 12.1, a second carrier film 12.2, a plurality of low-temperature interconnect ribbons 13, and a plurality of N-type solar cells 14. The plurality of N-type solar cells are disposed side by side. Every two adjacent N-type solar cells are interconnected using one of the plurality of low-temperature interconnect ribbons 13. Specifically, one end of one of the plurality of low-temperature interconnect ribbons 13 is connected to the front surface of one of the plurality of N-type solar cells, and the other end of the same low-temperature interconnect ribbon is connected to the rear surface of the adjacent N-type solar cell. The arrangement allows for alternating connection of positive electrodes and negative electrodes.

The first carrier film 12.1 is disposed on the front surface of each of the plurality of N-type solar cells 14. The second carrier film 12.2 is disposed on the rear surface of each of the plurality of N-type solar cells. The plurality of low-temperature interconnect ribbons 13 are adhered to the first carrier film and the second carrier film, thereby forming the plurality of N-type solar cell strings.

The solar cell assembly further comprises a plurality of ribbons 20; the plurality of ribbons 20 are disposed between the plurality of solar cell strings 17 to collect and conduct electricity. The arrangement forms the at least one solar array. The solar cell assembly further comprises a first encapsulant film 15.1, a second encapsulant film 15.2, a first sheet 16.1, and a second sheet 16.2. The first encapsulant film 15.1 is disposed on a front surface of the at least one solar array. The second encapsulant film 15.2 is disposed on a rear surface of the at least one solar array. The first sheet 16.1 is disposed on the first encapsulant film 15.1, and the second sheet 16.2 is disposed on the second encapsulant film 15.2.

The solar cell assembly further comprises a split-type junction box 18 disposed on the second sheet 16.2.

The solar cell assembly further comprises a first frame 19.1 and a second frame 19.2. A short edge of the at least one solar array is encapsulated with the first frame 19.1, and a long edge of the at least one solar array is encapsulated with the second frame 19.2.

The plurality of low-temperature interconnect ribbons are a plurality of low-temperature alloy copper wires.

The following advantages are associated with the disclosure:
(1) The disclosed N-type solar cell is a TOPCon solar cell that combines zero busbar (0BB) technology and half-cell technology. The design reduces the amount of silver needed in metallization process. Conventional Super Multi Busbar (SMBB) cells uses about 12 grams of the silver paste per watt of power output. By adopting the 0BB technology, the silver paste usage is reduced by 8 grams per watt, leading to a 30% reduction in the cost associated with the silver paste. By adopting the half-cell technology, the N-type solar cell is pre-cut into half cells to minimize the electrical losses that are typically caused by laser cutting processes, leading to lower overall power losses.
(2) With the 0BB technology, the thickness of the silicon wafers is reduced to from 130 μm to 100 μm, leading to material savings and cost reduction.
(3) The implement of 0BB technology allows the N-type solar cell to achieve an 85% bifacial coefficient, compared to 75% for the P-type solar cells.
(4) The disclosure utilizes more than 20 low-temperature alloy copper wires, each with a diameter of ≤0.2 mm, to interconnect the N-type solar cells. The improvement avoids high-temperature soldering, reducing thermal stress on the N-type solar cells, and contributes to more environmentally friendly solar technology by eliminating the need for lead.
(5) Instead of using soldering technology, the disclosure employs encapsulating films to provide the N-type solar cell with better resistance to environmental temperature and humidity, thereby reducing costs and making the production more eco-friendly.
(6) The 0BB technology eliminates the optical losses caused by the misalignment of solder wires and the busbars. With a higher density of the low-temperature alloy copper wires, a distance that charge carriers need to travel to reach a collection point is reduced. The short distance leads to lower electrical resistance and reduced electrical losses as the charge carriers move through the N-type solar cells.
(7) In the disclosure, the low-temperature interconnect ribbons are thinner in diameter and arranged more densely. The improvement enhances the ability of the N-type solar cell to collect electrical current more effectively and reduces attenuation caused by the hidden cracks in the N-type solar cells.
(8) The disclosure uses finer interconnect ribbons and thinner silicon wafers in the N-type solar cells. Additionally, the weight of the encapsulant films is reduced from 430 g for the SMBB cells to below 300 g. The changes leads to over a 30% reduction in costs.
(9) The solar cell assembly is assembled at around 150° C., which is considered a low temperature compared to conventional methods that require higher temperatures. The low-temperature assembling process has high carbon efficiency and lower manufacturing costs.
(10) The PAD points on the surface of the N-type solar cells are eliminated. Additionally, with the interconnect ribbons becoming thinner and more densely arranged, the reflectivity at the connection points is reduced. The denser arrangement enhances the uniformity of the appearance, resulting in a more aesthetically pleasing product.

The improvements collectively reduce electrical losses when the N-type solar cells are assembled into a solar cell assembly, achieving over 101% CTM efficiency (including contributions from double-sided coated glass (+0.5%), half-cut cells (+0.2%), 0BB technology (+1%), light conversion films (+0.3%), and reflective films (+0.3%)). The enhancement results in higher power per unit area and lower product costs. Additionally, the reliability of the N-type solar cell is improved, with first-year degradation limited to ≤1% and linear annual degradation <0.4%.

What is claimed is:

1. An N-type solar cell, comprising:
an N-type silicon substrate, an emitter layer, a first tunneling layer, at least one first doped polysilicon layer, a passivation layer, a first anti-reflection coating, a second tunneling layer, at least one second doped polysilicon layer, and a second anti-reflection coating;
wherein,
the emitter layer is disposed on a front surface of the N-type silicon substrate; the first tunneling layer is disposed on the emitter layer; the at least one first doped polysilicon layer is disposed on the first tunneling layer; the passivation layer is disposed on the at least one first doped polysilicon layer; the first anti-reflection coating is disposed on the passivation layer; the second tunneling layer is disposed on a rear surface of the N-type silicon substrate; the at least one second doped polysilicon layer is disposed on the second tunneling layer; and the second anti-reflection coating is disposed on the at least one second doped polysilicon layer.

2. The N-type solar cell of claim 1, wherein the N-type solar cell further comprises a plurality of first fingers disposed on an outer side of the first anti-reflection coating.

3. The N-type solar cell of claim 1, wherein the N-type solar cell further comprises a plurality of second fingers disposed on an outer side of the second anti-reflection coating.

4. The N-type solar cell of claim 1, wherein the first tunneling layer and the second tunneling layer comprise silicon dioxide.

5. The N-type solar cell of claim 1, wherein the passivation layer comprises aluminum oxide.

6. A solar cell assembly, comprising at least one solar array;
wherein,
the at least one solar array comprises a plurality of solar cell strings connected in series and/or in parallel; each of the plurality of solar cell strings comprises a first carrier film, a second carrier film, a plurality of low-temperature interconnect ribbons, and a plurality of N-type solar cells; the plurality of N-type solar cells are disposed side by side, and comprise an N-type silicon substrate, an emitter layer, a first tunneling layer, at least one first doped polysilicon layer, a passivation layer, a first anti-reflection coating, a second tunneling layer, at least one second doped polysilicon layer, and a second anti-reflection coating;
the emitter layer is disposed on a front surface of the N-type silicon substrate; the first tunneling layer is disposed on the emitter layer; the at least one first doped polysilicon layer is disposed on the first tunneling layer; the passivation layer is disposed on the at least one first doped polysilicon layer; the first anti-reflection coating is disposed on the passivation layer; the second tunneling layer is disposed on a rear surface of the N-type silicon substrate; the at least one second doped polysilicon layer is disposed on the second tunneling layer; and the second anti-reflection coating is disposed on the at least one second doped polysilicon layer; and
every two adjacent N-type solar cells are interconnected using one of the plurality of low-temperature interconnect ribbons; one end of one of the plurality of low-temperature interconnect ribbons is connected to the front surface of one of the plurality of N-type solar cells, and the other end of the low-temperature interconnect ribbon is connected to the rear surface of an adjacent N-type solar cell; the first carrier film is disposed on the front surface of each of the plurality of N-type solar cells; the second carrier film is disposed on a rear surface of each of the plurality of N-type solar cells; the plurality of low-temperature interconnect ribbons are adhered to the first carrier film and the second carrier film, thereby forming the plurality of solar cell strings; the solar cell assembly further comprises a plurality of ribbons; the plurality of ribbons are disposed between the plurality of solar cell strings to collect and conduct electricity; and the arrangement forms the at least one solar array.

7. The solar cell assembly of claim 6, wherein the solar cell assembly further comprises a first encapsulant film, a second encapsulant film, a first sheet, and a second sheet; the first encapsulant film is disposed on a front surface of the at least one solar array; the second encapsulant film is disposed on a rear surface of the at least one solar array; the first sheet is disposed on the first encapsulant film; and the second sheet is disposed on the second encapsulant film.

8. The solar cell assembly of claim 7, wherein the solar cell assembly further comprises a split-type junction box disposed on the second sheet.

9. The solar cell assembly of claim 6, wherein the solar cell assembly further comprises a first frame and a second frame; a short edge of the at least one solar array is encapsulated with the first frame; and a long edge of the at least one solar array is encapsulated with the second frame.

10. The solar cell assembly of claim 6, wherein the plurality of low-temperature interconnect ribbons are a plurality of low-temperature alloy copper wires.
